(19) United States
(12) Patent Application Publication
(10) Pub. No.: US 2004/0079997 A1
(43) Pub. Date: Apr. 29, 2004

(54) Semiconductor device and metal-oxide-semiconductor field-effect transistor

(76) Inventor: Noriyuki Miura, Kanagawa (JP)

Correspondence Address: RABIN & Berdo, PC, 1101 14TH STREET, NW, SUITE 500, WASHINGTON, DC, 20005, US

(21) Appl. No.: 10/690,579

(22) Filed: Oct. 23, 2003

(30) Foreign Application Priority Data
Oct. 24, 2002 (JP) 2002-309164
Feb. 24, 2003 (JP) 2003-045331

(51) Int. Cl. H01L 27/01

(52) U.S. Cl. 257/347

(57) ABSTRACT

A semiconductor device includes a semiconductor substrate, an insulating layer disposed on the semiconductor substrate, an SOI film disposed on the insulating layer, a gate insulator disposed on the SOI film, and a gate electrode disposed on the gate insulator. A source, a drain, and a channel are formed in the SOI film so that the gate insulator is located at least between the channel and the gate electrode, thereby forming a MOSFET including the source, the drain, the channel, the gate electrode, and the gate insulator. The gate electrode is made of P-type polysilicon doped with P-type impurities such as boron. Further, the channel is doped with N-type impurities such as arsenic or phosphorus.

### BACKGROUND OF THE INVENTION

1. Field of the Invention

The present invention relates to a semiconductor device including a silicon-on-insulator metal-oxide-semiconductor field-effect transistor (SOI MOSFET), and a method of fabricating such semiconductor device.

2. Description of the Related Art

Conventional SOI MOSFETs are disclosed in, for example, Japanese Patent Kokai (Laying open) Publication No. 2001-284590 and Proc. IEDM 93, pp. 723-726, Lisa T. Su, et al., “Optimization of Series Resistance in Sub-0.2 μm SOI MOSFETs.”

In the conventional SOI MOSFETs, as a gate length becomes shorter in accordance with the decrease of the size of the semiconductor element, the short channel effect (SCE) becomes more pronounced. This results in problems such as the decrease of the gate threshold voltage and the increase of variations of the gate threshold voltage due to variations of the gate length of the MOSFET products. In order to resolve such SCE problems, an SOI film is generally thinned.

However, an OFF-state leakage current increases when the SOI film is thinned. This is a significant problem in a small-sized portable product such as a cellular phone which places great importance on battery-saving. In order to reduce the OFF-state leakage current, it is necessary to make a gate threshold voltage high. Therefore, a high impurity concentration in the SOI film is required. However, a high impurity concentration in the SOI film leads to the increase of a collision frequency of carriers and the decrease of mobility of carriers, thereby degrading the driving performance of an SOI MOSFET.

### SUMMARY OF THE INVENTION

It is an object of the present invention to provide a semiconductor device that makes it possible to reduce an OFF-state leakage current while avoiding the degradation in driving performance, and a method of fabricating such semiconductor device.

According to the present invention, a semiconductor device includes a semiconductor substrate, an insulating layer disposed on the semiconductor substrate, an SOI film disposed on the insulating layer, a gate insulator disposed on the SOI film, and a gate electrode disposed on the gate insulator. Further, a source, a drain, and a channel are formed in the SOI film so that the gate insulator is located at least between the channel and the gate electrode, thereby forming a MOSFET including the source, the drain, the channel, the gate electrode, and the gate insulator. Furthermore, the gate electrode is made of P-type polysilicon, and the channel is N-type.

According to another aspect of the present invention, a metal-oxide-semiconductor field-effect transistor includes a semiconductor substrate having a substrate, an insulating layer which is disposed on the substrate and a silicon layer which is disposed on the insulating layer, a gate insulator disposed on the silicon layer of the semiconductor substrate, a gate electrode, which is made of P-type polysilicon, disposed on the semiconductor substrate so that the gate insulator is disposed between the gate electrode and the semiconductor substrate, a channel region formed in the silicon layer, which is located under the gate electrode, and a source and a drain formed in the silicon layer and being adjacent to the channel region, wherein conductivity types of the channel region, the source and the drain are N-type.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a cross sectional view schematically showing a semiconductor device in accordance with a first embodiment of the present invention;

FIG. 2 shows graphs indicating impurity concentration distributions along a direction of a gate length in an SOI film of a semiconductor device in accordance with the first embodiment respectively;

FIG. 3 shows graphs indicating gate length versus gate threshold voltage relationships in an SOI MOSFET of the first embodiment and an example to be compared respectively;

FIG. 4 shows graphs indicating gate voltage versus drain current relationships in an SOI MOSFET of the first embodiment and an example to be compared respectively;

FIG. 5 shows graphs indicating drain voltage versus drain current relationships in an SOI MOSFET of the first embodiment and an example to be compared respectively;

FIGS. 6A to 6F are cross sectional views each schematically showing a process in a method of fabricating a semiconductor device including an SOI MOSFET in accordance with the first embodiment of the present invention;

FIGS. 7A to 7E are cross sectional views each schematically showing a process in a method of fabricating a semiconductor device including an SOI MOSFET in accordance with a second embodiment of the present invention; and

FIGS. 8A to 8D show impurity concentration profiles along a direction of a depth in an SOI MOSFET in accordance with the second embodiment of the present invention respectively.

### DETAILED DESCRIPTION OF THE PREFERRED EMBODIMENTS

Further scope of applicability of the present invention will become apparent from the detailed description given hereinafter. However, it should be understood that the detailed description and specific examples, while indicating preferred embodiments of the invention, are given by way of illustration only, since various changes and modifications will become apparent to those skilled in the art from the detailed description.

First Embodiment

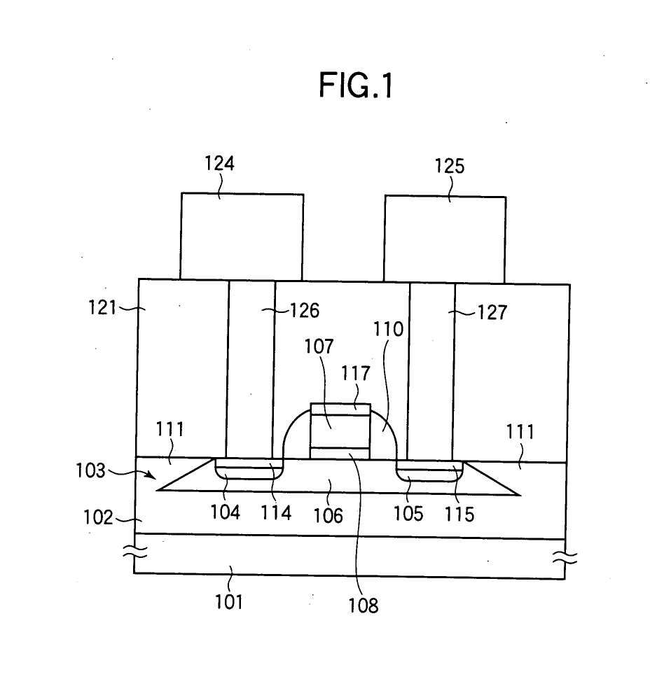

FIG. 1 is a cross sectional view schematically showing a semiconductor device including a silicon-on-insulator metal-oxide-semiconductor field-effect transistor (SOI MOSFET) in accordance with the first embodiment of the present invention.

As shown in FIG. 1, the semiconductor device includes a semiconductor substrate 101, an insulating layer 102, i.e., a buried oxide (BOX) layer disposed on the semiconductor substrate 101, and a semiconductor film, i.e., an SOI film 103 disposed on the insulating layer 102. The semiconductor substrate 101 is made of silicon, the insulating layer 102 is made of silicon oxide (SiO₂), and the SOI film 103 is made of silicon, for example. A thickness of the SOI film 103 is within a range approximately from 10 nm to 40 nm, and preferably approximately 20 nm. This is because when the thickness of the SOI film 103 is approximately 20 nm, a fully-depleted channel structure of the MOSFET can be formed in the SOI film 103.

A source 104, a drain 105, and a channel 106 disposed between the source 104 and the drain 105 are formed in a first region (a region where the source is to be formed), a second region (a region where the drain is to be formed), and a third region (a region where the channel is to be formed) of the SOI film 103 respectively. Further, titanium silicide (TiSi₂) layers 114 and 115 are formed on upper surfaces of the source 104 and the drain 105 respectively.

As shown in FIG. 1, a gate insulator 108 is disposed on the channel 106, and a gate electrode 107 is disposed on the gate insulator 108 so that the gate electrode 107 is located directly above the channel 106. Further, a titanium silicide (TiSi₂) layer 117 is formed on an upper surface of the gate electrode 107, and sidewall spacers 110 are disposed on both sides of the gate electrode 107 and the gate insulator 108.

An SOI MOSFET, which is an SOI N-channel type MOSFET (SOI NMOSFET) in this embodiment, is composed of the source 104, the drain 105, the channel 106, the gate electrode 107, the gate insulator 108, and the sidewall spacers 110.

The SOI MOSFET shown in FIG. 1 is electrically isolated from adjacent elements (not shown) such as other SOI MOSFETs by an isolation layer 111, which is formed using the local oxidation of silicon (LOCOS) method or the shallow trench isolation (STI) method, for example.

As shown in FIG. 1, the SOI film 103, the gate electrode 107, and the isolation layer 111 are covered with an interlayer dielectric 121. Metal wiring layers 124 and 125 are disposed on the interlayer dielectric 121. The metal wiring layer 124 is electrically connected to the titanium silicide layer 114 disposed on the source 104 via a contact plug 126 which penetrates the interlayer dielectric 121. Further, the metal wiring layer 125 is electrically connected to the titanium silicide layer 115 disposed on the drain 105 via a contact plug 127 which penetrates the interlayer dielectric 121. The contact plugs 126 and 127 are made of tungsten, for example.

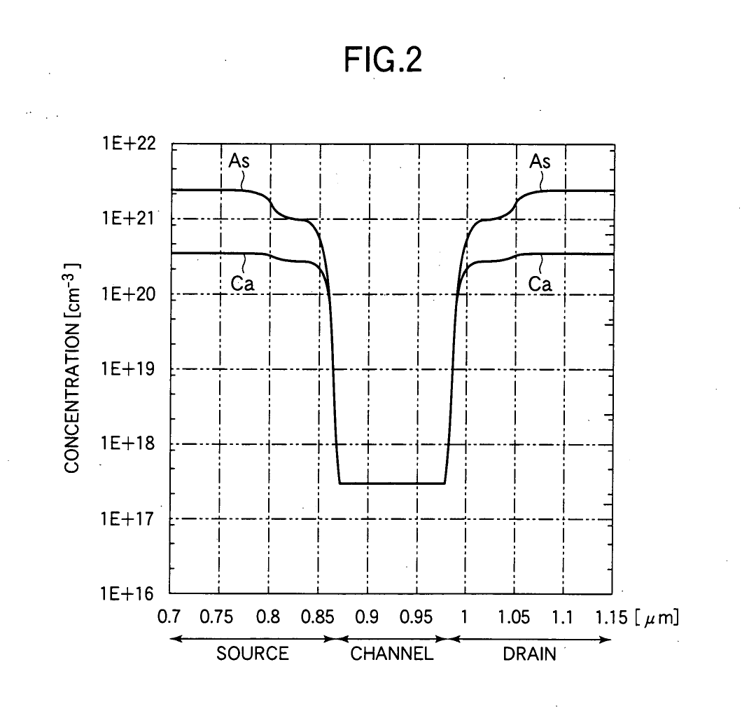

The source 104 and the drain 105 are N⁺-type and include arsenic (As) as dopant atoms (i.e., impurities). An N-type impurity concentration in the source 104 and the drain 105 is not less than approximately 1×10²¹ cm⁻³, and preferably approximately 2×10²¹ cm⁻³. In the drawings, an expression “1E21 /cm³” or “1E+21/cm³” means 1×10²¹ cm⁻³, for example. The channel 106 is N-type and includes arsenic (As) as dopant atoms (i.e., impurities). An N-type impurity concentration in the channel 106 is within a range approximately from 1×10¹⁷ cm⁻³ to 1×10¹⁸ cm ⁻³, and preferably approximately 3×10¹⁷ cm⁻³. FIG. 2 shows graphs indicating N-type impurity concentration profiles in the SOI film 103, i.e., impurity concentration distributions along a direction of a channel length respectively. In FIG. 2, a curve “As” indicates an arsenic concentration profile, and a curve “Ca” indicates a carrier concentration profile.

The gate electrode 107 is made of P-type (strictly speaking, P⁺-type) polysilicon doped with boron (B). The gate insulator 107 is made of silicon oxide (SiO₂). A thickness of the gate insulator 107 is within a range approximately from 1 nm to 4 nm, and preferably approximately 2 nm.

In the SOI MOSFET of the first embodiment, a subthreshold factor (S-factor) is 70 millivolt/decade (mV/dec). Further, a gate length (or a channel length) is within a range approximately from 0.1 μm to 0.25 μm, and preferably approximately 0.15 μm. Furthermore, a gate threshold voltage Vt is approximately 0.36 V. An OFF-state leakage current per unit gate width, i.e., a normalized OFF-state leakage current I_{off}/W is 1×10⁻¹¹ ampere/micrometer (A/μm), where I_{off} represents an actual OFF-state leakage current and W represents a gate width. The normalized OFF-state leakage current is also referred to as “an OFF-state leakage current” in the following description. There are two definitions of the gate threshold voltage. One defines the gate threshold voltage Vt using the constant current method. The other defines the gate threshold voltage Vₜₕ using inversion-layer formation. The both gate threshold voltages Vₜ and Vₜₕ are approximately equal.

The gate threshold voltage Vₜ defined by the constant current method is a gate voltage when a predetermined current Iₜ ampere (A) flows through the gate. The current Iₜ is expressed by the following expression.

Iₜ=0.1×(W/L)×(1×10⁻⁶) (A)

where W represents a gate width and L represents a gate length. When a gate length L is 0.15 μm, a current per unit gate width expressed in a unit of micrometer (μm), i.e., a normalized current Iₜ/W is expressed by the following expression.

$$\begin{matrix}{I}_{ t} / W = 0.1 \times ( 1 / 0.15 ) \times ( 1 \times {10}^{- 6} ) ( A \text{/} µm ) \\ = 6.67 \times {10}^{- 7} ( A \text{/} µm )\end{matrix}$$

Therefore, the gate threshold voltage Vₜ is defined as a gate voltage when the normalized current Iₜ/W is 6.67×10⁻⁷ A/μm.

The gate threshold voltage Vₜ defined by the constant current method is directly linked to an OFF-state leakage current I_{off} Therefore, it is convenient that the gate threshold voltage Vₜ defined by the constant current method is used when examining the OFF-state leakage current I_{off}. On the other hand, it is convenient that the gate threshold voltage Vₜₕ defined using inversion-layer formation is used when examining materials of the respective parts of the MOSFET or a relationship between an impurity concentration in the MOSFET and a gate threshold voltage. When a gate length of the MOSFET is approximately 5 μm or more, a gate threshold voltage Vₜₕ defined using inversion-layer formation can be obtained comparatively accurately by a calculation on the basis of various conditions such as an impurity concentration in a channel, materials of a gate electrode, and a thickness of a gate insulator. However, when a gate length of the MOSFET is approximately 1 μm or less, it is difficult to obtain a gate threshold voltage-Vth defined using inversion-layer formation by a calculation on the basis of the above-mentioned various conditions, because it is necessary to estimate the decrease (roll-off) of the gate threshold voltage Vth in consideration of the short channel effect (SCE).

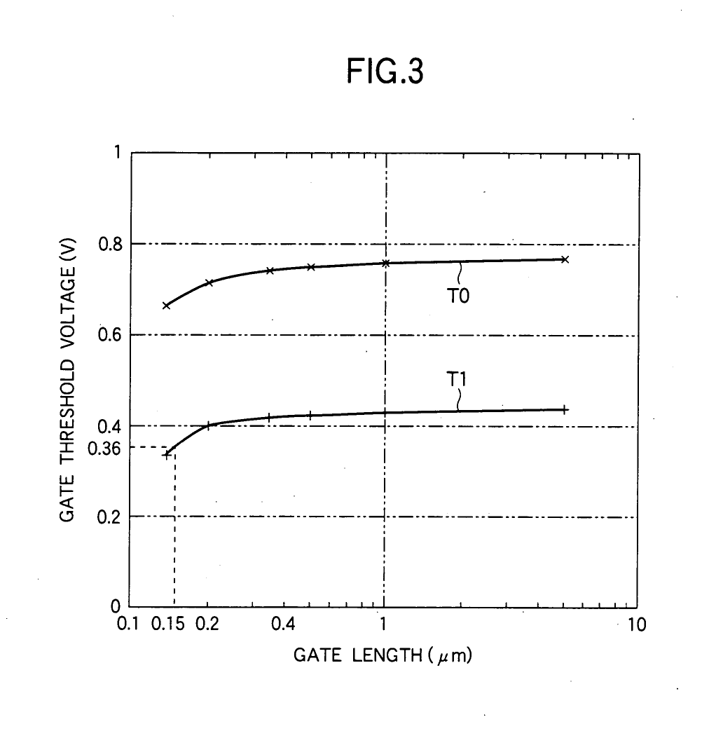

FIG. 3 shows graphs indicating gate length versus gate threshold voltage relationships in an SOI MOSFET of the first embodiment (T1) and an example (T0) to be compared respectively. Data in FIG. 3 were obtained by a simulation on condition that a gate electrode is made of P⁺-type polysilicon, a channel is N-type, an N-type impurity concentration in the channel is 3×10¹⁷ cm⁻³, and a work function of the gate electrode is 5.27 eV. In FIG. 3, a curve T1 indicates a case of the first embodiment, in which an N-type impurity concentration in the channel is 3×10¹⁷ cm⁻³. Further, a curve T0 indicates a case of the example to be compared, in which an N-type impurity concentration in the channel is approximately zero or enough low (i.e., approximately 1×10¹¹ cm⁻³ or less).

As can be understood from the curve T0 in FIG. 3 indicating a case where the N-type impurity concentration in the channel is approximately zero, a gate threshold voltage is approximately 0.73 V when the gate length is approximately 0.4 μm or more. Further, as can be understood from a curve T1 in FIG. 3 indicating a case where the N-type impurity concentration in the channel is increased by introducing impurities into the channel, a gate threshold voltage decreases by approximately 0.3 V as compared with the curve T0 so that the gate threshold voltage becomes approximately 0.44 V when the gate length is approximately 0.4 μm or more. When the gate length is less than 0.4 μm, a gate threshold voltage falls down. In a case of the curve T1, a gate threshold voltage is approximately 0.4 V at a gate length of 0.2 μm, and approximately 0.36 V at a gate length of 0.15 μm. In a case of the curve T0 where the N-type impurity concentration in the channel is approximately zero, a gate threshold voltage falls down in a similar manner to a case of the curve T1 where the N-type impurity concentration in the channel is approximately 3×10¹⁷ cm⁻³.

As can be understood from FIG. 3, a gate threshold voltage can be decreased by increasing the N-type impurity concentration in the channel, that is, a gate threshold voltage can be adjusted by controlling the N-type impurity concentration in the channel.

As mentioned above, a gate threshold voltage Vt defined by the constant current method is linked to a normalized OFF-state leakage current I_{off}/W, and the normalized OFF-state leakage current I_{off}/W decreases as the gate threshold voltage Vₜ increases. For example, in a fully-depleted MOSFET, the S-factor of which is generally 70 mV/dec, if the gate threshold voltage Vₜ defined by the constant current method is 0.337 V, a normalized OFF-state leakage current I_{off}/W becomes 1×10⁻¹¹ A/μm. Accordingly, it is preferable that a gate threshold voltage be more than 0.337 V, and a gate threshold voltage of 0.36 V satisfies this preferable condition.

In the first embodiment, since the gate electrode is made of P⁺-type polysilicon, the channel of the SOI film 103 is N-type, and a gate threshold voltage is approximately 0.36 V, a normalized OFF-state leakage current I_{off}/W can be suppressed. Further, in the first embodiment, since the N-type impurity concentration in the channel is at a low level such as approximately 3×10¹⁷ cm⁻³, the decrease of mobility of carriers can be avoided. As a result, an ON-state current Iₒₙ (a drain current in ON-state) can be increased.

Although an OFF-state leakage current decreases as the gate threshold voltage increases, there is a problem that an operational speed decreases because an ON-state current becomes small. On the basis of these points, an upper limit of the gate threshold voltage can be determined, and the gate threshold voltage of approximately 0.36 V is an adequate level.

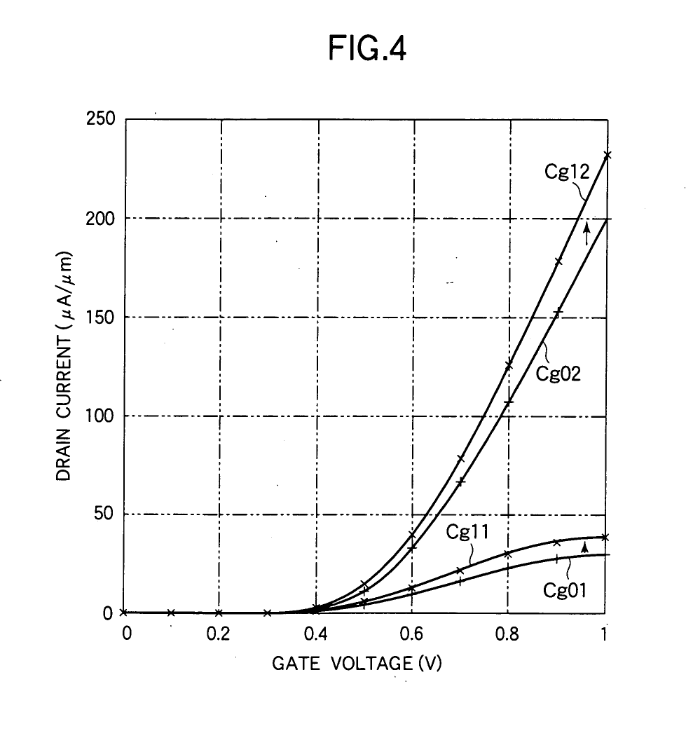

FIG. 4 shows graphs indicating gate voltage versus drain current relationships in an SOI MOSFET of the first embodiment (Cg11, Cg11) and an example (Cg01, Cg02) to be compared respectively. Data in FIG. 4 were obtained by a simulation on condition that a gate electrode is made of P⁺-type polysilicon, a channel is N-type, an N-type impurity concentration in the channel is 3×10¹⁷ cm⁻³, and a gate threshold voltage is 0.4 V. A curve Cg11 indicates a case where the drain voltage is 50 mV, and a curve Cg12 indicates a case where the drain voltage is 1.0 V.

FIG. 5 shows graphs indicating drain voltage versus drain current relationships in an SOI MOSFET of the first embodiment (Cd11, Cd12, Cd13) and an example (Cd01, Cd02, Cd03) to be compared respectively. Data in FIG. 5 were obtained by a simulation on condition that a gate electrode is made of P⁺-type polysilicon, a channel is N-type, an N-type impurity concentration in the channel is 3×10¹⁷ cm⁻³, and a gate threshold voltage is 0.4 V. A curve Cd11 indicates a case where a gate voltage is 0.5 V, a curve Cd12 indicates a case where a gate voltage is 0.75 V, and a curve Cg13 indicates a case where the drain voltage is 1.0 V.

In FIGS. 4 and 5, curves each indicating a drain current in an example to be compared are also illustrated. The curves Cg01, Cg02, Cd01, Cd02, and Cd03 indicating the examples to be compared correspond to the curves Cg11, Cg12, Cd11, Cd12, and Cd13 indicating the present invention respectively. In the examples to be compared, a channel is P-type, a P-type impurity concentration in the channel is 2×10¹⁸ cm⁻³, a gate electrode is made of N-type polysilicon, and the other conditions are similar to those shown in FIG. 1. It can be understood from FIGS. 4 and 5 that a drain current increases by at least 10% with respect to the corresponding example to be compared by adopting the above-described configuration of the present invention.

A gate threshold voltage Vₜₕ defined using the inversion-layer formation will be studied below in order to study materials of each part of the MOSFET and the impurity concentration in a channel of the MOSFET. The gate threshold voltage Vₜₕ is given by the following expressions (1) and (2).

Vₜₕ=V_{fb}+Φ_{f}−q×N_{d}×Tₛₒᵢ/Cₒₓ (1)

where V_{fb} represents a flat band voltage and is expressed by the following expression.

V_{fb}=Wₘ−Wₛ−Qₒₓ/Cₒₓ (2)

In the expression (2), Wₘ represents a work function of the gate electrode and is, for example, approximately 5.27 V when the gate electrode is made of P⁺-type polysilicon. Further, Wₛ is a work function of silicon constituting the channel, and is, for example, approximately 4.7 V.

In the third term on the right-hand side of the expression (2), Qₒₓ represents an interface charge density, and is obtained by the product (positive value) of a fixed electrical charge amount per a unit area 4×10¹² cm⁻² and an elementary charge 1.6×10⁻¹⁹ Coulomb (C). Accordingly

$$\begin{matrix}{Q}_{ox} = 4 \times {10}^{12} ( {cm}^{- 2} ) \times 1.6 \times {10}^{- 19} ( C ) \\ = 6.4 \times {10}^{- 7} ( C \text{/} {cm}^{2} )\end{matrix}$$

In the third term on the right-hand side of the expression (2), Cox represents capacitance of a gate oxide film (i.e., the gate insulator) and is 1.73×10⁻⁶ farad/square centimeter (F/cm²), for example.

Accordingly, the third term on the right-hand side of the expression (2) is expressed by the following expression.

$$\begin{matrix}{Q}_{ox} / {C}_{ox} = 6.4 \times {10}^{- 7} ( C \text{/} {cm}^{2} ) / 1.73 \times {10}^{- 6} ( F \text{/} {cm}^{2} ) \\ = 0.4 ( V )\end{matrix}$$

Therefore, the first term on the right-hand side of the expression (1) is determined when materials of a gate electrode are determined. In the above-mentioned example, the first term on the right-hand side is expressed by the following expression.

$$\begin{matrix}{V}_{f b} = {W}_{m} - {W}_{s} - {Q}_{ox} / {C}_{ox} \\ = 5.27 ( V ) - 4.7 ( V ) - 0.4 ( V ) \\ = 0.17 ( V )\end{matrix}$$

In the second term on the right-hand side of the expression (1), a value Φ_{f}, which depends on the impurity concentration in the channel, decreases as the impurity concentration in the channel increases. When the impurity concentration N_{d} in the channel is approximately zero, Φ_{f} is approximately 0.56 V. When the impurity concentration N_{d} is approximately 3×10¹⁷ cm⁻³, Φ_{f} is approximately 0.38 V.

Further, in the third term on the right-hand side of the expression (1), q represents an elementary charge which is 1.6×10¹⁹ C. Further, N_{d} represents an impurity concentration in the channel (a body of the SOI film), Tₛₒᵢ represents a thickness of the SOI film, and is, for example, 20 nm, and Cₒₓ represents capacitance of a gate oxide film as a gate insulator and is, for example, 1.73×10⁻⁶ F/cm².

When the impurity concentration N_{d} in the channel is approximately zero or enough small, the third term on the right-hand side in the equation (1) is approximately zero. Further, as described above, the second term on the right-hand side in the equation (1) is 0.56 V. Therefore, the gate threshold voltage Vₜₕ is approximately 0.73 V.

When the N-type impurity concentration in the channel is 3×10¹⁷ cm⁻³, the third term on the right-hand side of the expression (1) is expressed by the following expression.

$$q \times {N}_{d} \times {T}_{soi} / {C}_{ox} = ( 1.6 \times {10}^{- 19} ) \times ( 3 \times {10}^{17} ) \times ( 2 \times {10}^{- 6} ) \times ( 1.73 \times {10}^{- 6} ) = 0.06 ( V ) \qquad ( 5 )$$

The right-hand side of the expression (1), i.e., the gate threshold voltage Vₜₕ is expressed as follows:

0.17+0.38−0.06=0.49 (V)

This is a value when the gate length is comparatively long (in case of 0.4 μm or more). This value decreases as the gate length decreases.

The value (Vₜₕ=0.49 (V)) shown above is slightly different from the value (Vₜ) expressed in FIG. 3. The reason why the difference takes place is because a factor that has been neglected when calculating the value Vₜₕ is considered in case of FIG. 3 (when calculating the value Vₜ).

As described above, in the first embodiment, when a gate electrode is made of P⁺-type polysilicon, a channel is N-type, the N-type impurity concentration in the channel is approximately 3×10¹⁷ cm⁻³, a gate length is 0.15 μm, and a gate threshold voltage becomes 0.36 V. As a result, a normalized OFF-state leakage current I_{off}/W is reduced to a desired value, and too small ON-state current can be avoided.

As described above, an OFF-state leakage current becomes enough small when a gate threshold voltage is 0.337 V or more. In the first embodiment, when a gate length is 0.15 μm, a gate threshold voltage becomes approximately 0.36 V. Accordingly, an SOI MOSFET, in which an OFF-state leakage current is small enough and an ON-state current is enough large, can be obtained.

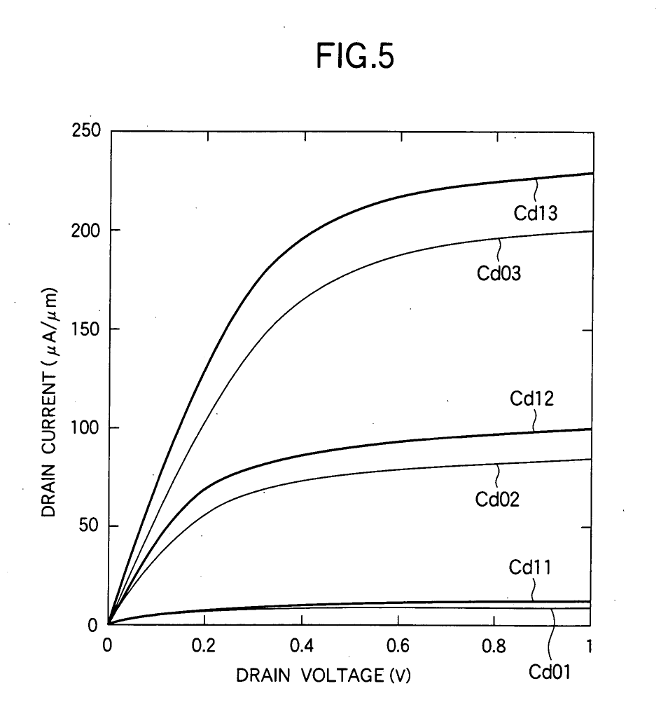

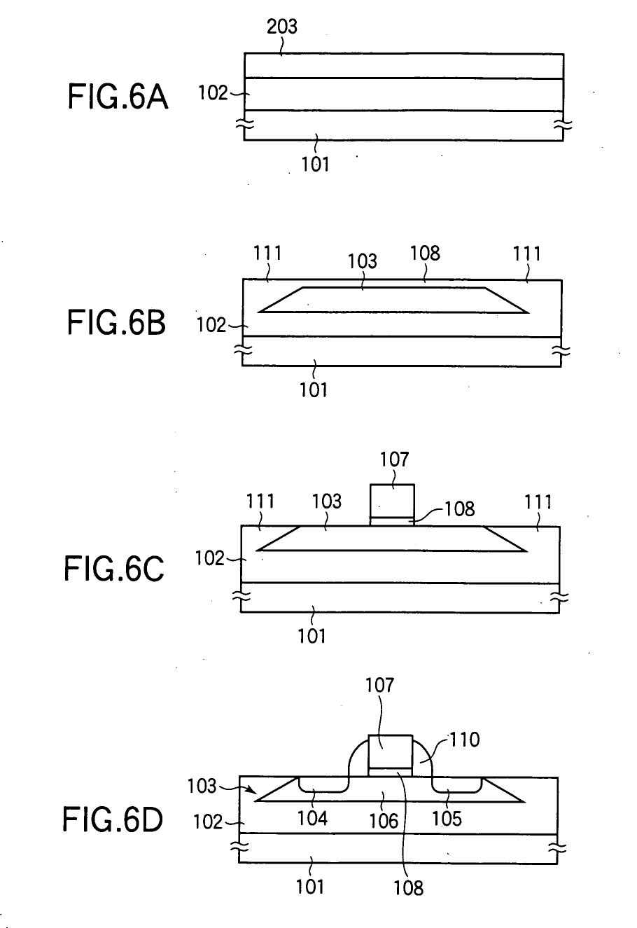

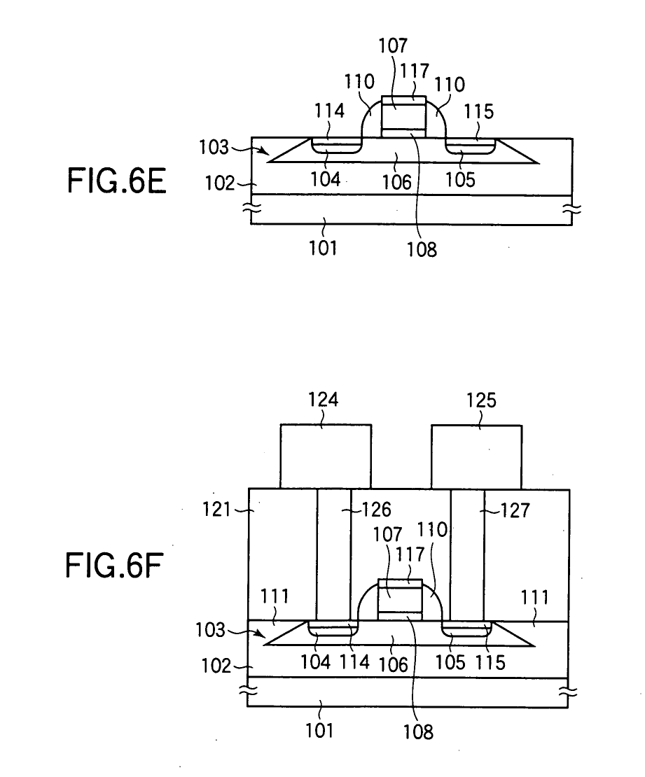

A method of fabricating a semiconductor device including the above-described SOI MOSFET will be described below. FIGS. 6A to 6F are cross sectional views each schematically showing a process in a method of fabricating a semiconductor device including such SOI MOSFET in accordance with the first embodiment.

First, an outline of the method of fabricating a semiconductor device will be described.

In the method of fabricating a semiconductor device, the semiconductor device includes a semiconductor substrate 101, an insulating layer 102 disposed on the semiconductor substrate 101, an SOI film 103 disposed on the insulating layer 102, a gate insulator 108 disposed on the SOI film 103, and a P-type gate electrode 107 disposed on the gate insulator 108, and a source 104, a drain 105, and a channel 106 are respectively formed in first, second, and third regions of the SOI film 103 so that the gate insulator 108 is located at least between the channel 106 and the gate electrode 107. The method includes: doping the SOI film 103 with N-type first impurities so that an N-type impurity concentration in the first, second, and third regions of the SOI film 103 is within a range approximately from 1×10¹⁷ cm⁻³ to 1×10¹⁸ cm⁻³; forming the gate insulator 108 on the SOI film 103 so as to cover the third region; forming the gate electrode 107 on the gate insulator 108; and doping the first and second regions of the SOI film 303 with N-type second impurities so that an N-type impurity concentration in the source 104 and the drain 105 is not less than approximately 1×10²¹ cm⁻³.

Further, in the method of fabricating a semiconductor device, the doping the SOI film 103 with N-type first impurities may be performed so that the N-type impurity concentration in the first, second, and third regions of the SOI film 103 is approximately 3×10¹⁷ cm⁻³.

Furthermore, in the method of fabricating a semiconductor device, the gate electrode may be made of polysilicon doped with boron as P-type impurities, and the N-type first and second impurities may include at least one of arsenic and phosphorus.

Moreover, in the method of fabricating a semiconductor device, the SOI film 103 and the semiconductor substrate 101 may be bonded together, and the doping the SOI film 103 with N-type first impurities may be performed before the bonding of the SOI film 103 and the semiconductor substrate 101. Alternatively, in the method of fabricating a semiconductor device, the SOI film 103 and the semiconductor substrate 101 may be bonded together, and the doping the SOI film 103 with N-type first impurities may be performed after the bonding of the SOI film 103 and the semiconductor substrate 101.

Next, a detail of the method of fabricating a semiconductor device will be described.

First, as shown in FIG. 6A, a composite substrate including a silicon substrate 101, an oxide layer 102 disposed on the silicon substrate 101, and a surface silicon film 203 is prepared. The SOI film (a reference 103 in FIG. 6B) is a part of the surface silicon film 203. The surface silicon film 203 of the composite substrate is subjected to sacrificial oxidation, and a sacrificial oxide layer is removed to adjust a thickness of the surface silicon film 203. As a result, a thickness of the surface silicon film 203 becomes approximately 22 nm, for example.

Next, as shown in FIG. 6B, an isolation layer (isolation oxidation layer, for example) 111 is formed by the LOCOS method or the STI method. Doping the isolation edge, i.e., channel stop implantation may be performed in order to restrict the occurrence of parasitic channel in the isolation edge.

Next, the surface silicon film 203 is doped with impurity ions for the purpose of controlling the gate threshold voltage of the MOSFET. In this process, ions are implanted into the whole of the surface silicon film 203. In the first embodiment, ions are implanted so that an arsenic (As) concentration in the whole of the surface silicon film 203 is approximately 3×10¹⁷ cm⁻³.

Next, as shown in FIG. 6B, a part of the surface silicon film 203 is oxidized to form a gate insulator 108. Among the surface silicon film 203, a part that was not oxidized becomes the SOI film 103. A thickness of the SOI film 103 is approximately 20 nm. Further, a thickness of the gate insulator 108 is approximately 2 nm. Furthermore, the gate insulator 108 may be made before the ion implantation for controlling the gate threshold voltage.

Next, as shown in FIG. 6C, a P⁺-type polysilicon gate electrode 107 is formed using the CVD method, for example. Impurities in the gate electrode 107 are boron (B), for example. A thickness of the gate electrode 107 is approximately 200 nm, for example. Further, the gate electrode may be doped with boron by reacting diborane (B₂H₆) simultaneously with the deposition process of the gate electrode, for example. Furthermore, boron may be implanted after the CVD process for forming the gate electrode 107. In the first embodiment, the silicon substrate 101 is P-type. The P-type impurity concentration in the polysilicon of the gate electrode 107 is higher than the P-type impurity concentration in the silicon substrate 101. In other words, the polysilicon gate electrode 107 is P⁺-type.

Next, as shown in FIG. 6C, a gate electrode 107 and a gate insulator 108 are patterned by etching using a resist pattern so that the MOSFET has a desired gate length.

Next, as shown in FIG. 6D, N-type impurities are implanted into the first region and the second region of the SOI film 103 to form a source 104 and a drain 105.

Next, as shown in FIG. 6D, sidewall spacers 110 of the gate electrode 107 are formed. The sidewall spacers 110 are made of SiO₂ or Si₃N₄, for example. Further, the source 104 and the drain 105 may be made after the sidewall spacers 110 are formed.

Halo implantation may be performed before the formation of the source 104 and the drain 105 for the purpose of suppressing the short channel effect.

Next, as shown in FIG. 6E, the silicide layers 114, 115, and 117 such as TiSi₂ are formed in order to reduce sheet resistances of the source 104 and the drain 105 in the SOI film 103 and the gate electrode 107.

The silicide layers 114, 115, and 117 are formed as follows. A metal such as titanium (Ti) is deposited, the first rapid thermal annealing (RTA) is performed at about 550 degrees to 650 degrees centigrade, unreacted metal such as Ti is selectively removed, and the second RTA is performed at about 700 degrees to 850 degrees centigrade. In the above description, TiSi₂ is used as the silicide layers, but the other material such as CoSi₂ or NiSi can be used as the silicide layers.

Next, as shown in FIG. 6F, an interlayer dielectric 121 is deposited, and then etched to form contact holes. Next, the contact plugs 126 and 127 are formed in the contact holes, and then the metal wiring layers 124 and 125 are formed so as to cover the contact plugs 126 and 127.

Through the above-described processes, the semiconductor device including the SOI MOSFET in accordance with the first embodiment has been completed.

In the above-mentioned manufacturing method, since an SOI film is doped with a single kind of dopant (i.e., only As), there is an advantage that the manufacturing steps are few in number and simple.

In the above description, after forming a composite substrate including a silicon substrate 101, an insulating layer 102, and a surface silicon film 203, a part of which becomes an SOI film 103, the SOI film 103 is doped with N-type impurities. However, before bonding the SOI film 103 or a surface silicon film 203 to the silicon substrate 101 so as to form the composite substrate, the SOI film 103 may be doped with N-type impurities.

Further, an SOI substrate including a silicon substrate 101, an insulating layer 102, and an SOI film 103 may be made through the separation by the implanting oxygen (SIMOX) method, in which oxygen ions are implanted into a silicon substrate to form an insulating layer and an SOI film.

In the above-described SOI MOSFET, the gate length is approximately 0.15 μm. However, the present invention can be applied to another SOI MOSFET which has a different gate length. Especially, a remarkable advantage can be obtained for the SOI MOSFET having a gate length within approximately from 0.1 μm to 0.25 μm.

As described above, the semiconductor device including an SOI MOSFET has advantages that the OFF-state leakage current is enough small, the ON-state current is enough large, and the operational speed is enough high.

Second Embodiment

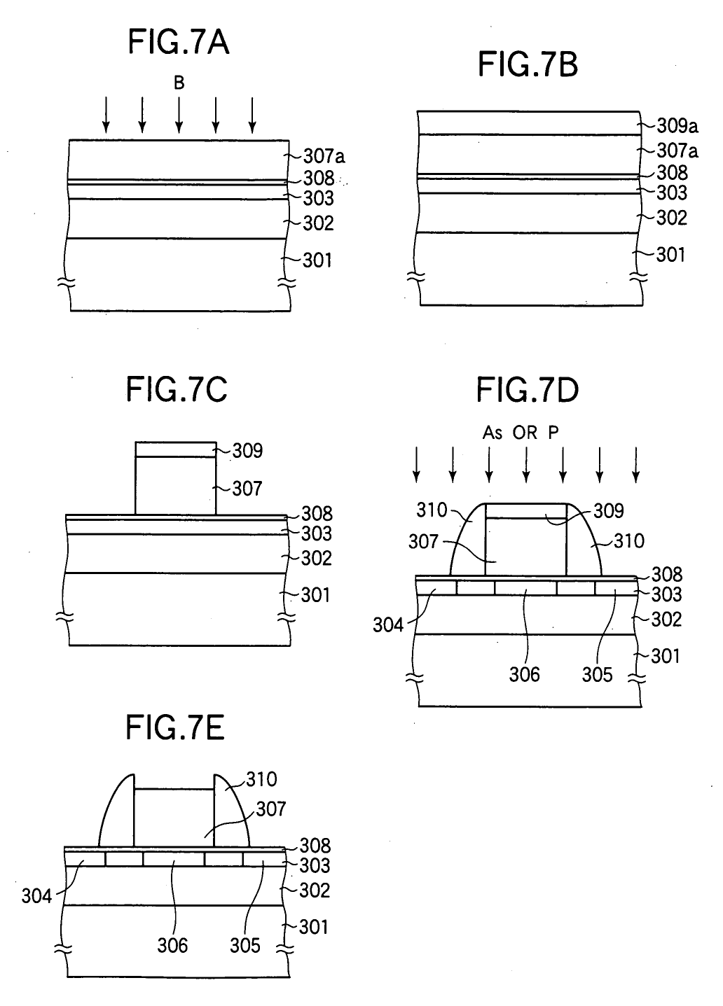

FIGS. 7A to 7E are cross sectional views each schematically showing a process in a method of fabricating a semiconductor device including an SOI MOSFET in accordance with the second embodiment of the present invention.

First, an outline of the method of fabricating a semiconductor device will be described.

In the method of fabricating a semiconductor device, the semiconductor device includes a semiconductor substrate 301, an insulating layer 302 disposed on the semiconductor substrate 301, an SOI film 303 disposed on the insulating layer 302, a gate insulator 308 disposed on the SOI film 303, and a P-type gate electrode 307 disposed on the gate insulator 308, and a source 304, a drain 305, and a channel 306 are respectively formed in first, second, and third regions of the SOI film 303 so that the gate insulator 308 is located at least between the channel 306 and the gate electrode 307. The method includes: doping the SOI film 303 with N-type first impurities; forming the gate insulator 308 on the SOI film 303 so as to cover the third region; forming the gate electrode 307 on the gate insulator 308; forming a cover film 309 on the gate electrode 307; and implanting N-type second impurities into the first and second regions of the SOI film 303 using the cover film 309 as a mask, thereby forming the source 304 and drain 305.

Further, in the method of fabricating a semiconductor device, the cover film 309 may be made of silicon oxide. Alternatively, the cover film 309 may be made of non-doped silicon oxide glass.

Moreover, in the method of fabricating a semiconductor device, a thickness of the cover film 309 may be substantially the same as a junction depth of diffusion layers forming the source 304 and drain 305.

Further, the method of fabricating a semiconductor device may further include removing the cover film 309 after the implanting the N-type second impurities 303. In addition, the method of fabricating a semiconductor device may further include forming a silicide layer on the gate electrode 307 after the removing the cover film 309.

Furthermore, the silicide layer may be made of cobalt silicide.

Moreover, in the method of fabricating a semiconductor device, the cover film 309 may be made of conductive material. Alternatively, the cover film 309 may be made of tungsten silicide.

Further, in the method of fabricating a semiconductor device, after the implanting the N-type second impurities, a P-type impurity concentration in the gate electrode 307 may be not less than approximately 1×10²⁰ cm⁻³.

Furthermore, in the method of fabricating a semiconductor device, a thickness of the gate electrode 307 may be within a range approximately from 100 nm to 200 nm. The thickness of the gate electrode 307 is preferably approximately 150 nm.

Moreover, in the method of fabricating a semiconductor device, the doping the SOI film 303 with the N-type first impurities may be performed so that an N-type impurity concentration in the first, second, and third regions of the SOI film 303 is within a range approximately from 1×10¹⁷ cm⁻³ to 1×10¹⁸ cm⁻³.

Further, the doping the SOI film 303 with the N-type first impurities may be performed so that the N-type impurity concentration in the first, second, and third regions of the SOI film 303 becomes approximately 3×10¹⁷ cm⁻³.

Furthermore, a thickness of the gate insulator 308 may be within a range approximately from 1 nm to 4 nm, and a thickness of the SOI film 303 may be within a range approximately from 10 nm to 40 nm. The thickness of the gate insulator 308 is preferably approximately 2 nm, and the thickness of the SOI film 303 is preferably approximately 20 nm.

Moreover, the implanting the N-type second impurities may be performed so that an N-type impurity concentration in the first and second regions of the SOI film 303 is not less than approximately 1×10²¹ cm⁻³.

Further, a channel length of the channel 306 may be within a range approximately from 0.1 μm to 0.25 μm. The channel length of the channel 306 is preferably approximately 0.15 μm.

Furthermore, the gate electrode 307 may be made of polysilicon doped with boron as P-type impurities, and the N-type first and second impurities may include at least one of arsenic and phosphorus.

Moreover, the SOI film 303 and the semiconductor substrate 301 are bonded together, and the doping the SOI film 303 with N-type first impurities may be performed after bonding of the SOI film 303 and the semiconductor substrate 301.

Next, a detail of the method of fabricating a semiconductor device will be described.

As shown in FIGS. 7A to 7E, in the second embodiment a composite substrate is prepared. The composite substrate includes a silicon substrate 301, an insulating layer, i.e., a buried oxide (BOX) layer 302 disposed on the silicon substrate 301, and a surface silicon film (a part of the surface silicon film becomes an SOI film 303) disposed on the BOX layer 302. The silicon substrate 301 is a P-type silicon substrate and the BOX layer 302 is a silicon oxide layer, for example. The SOI film is electrically isolated from other SOI films as in the similar manner to the first embodiment (FIG. 1).

Next, N-type impurities (i.e., dopant ions) are implanted into the surface silicon film to adjust a gate threshold voltage of the MOSFET and to form an N-type region as a body of the MOSFET. The N-type impurities are introduced into the whole surface silicon film including a first region (a region where a source 304 is to be formed), a second region (a region where a drain 305 is to be formed), and a third region (a region where a channel 306 is to be formed). In this implanting process of N-type impurities, arsenic (As) atoms are implanted into the surface silicon film so that N-type impurity concentration in the SOI film 303 is within a range approximately from 1×10¹⁷ cm⁻³ to 1×10¹⁸ cm⁻³, for example. It is preferable that an N-type impurity concentration in the SOI film 303 be approximately 3×10¹⁷ cm⁻³, for example.

Next, a surface of the surface silicon film is oxidized to form the gate insulator 308. Although the gate insulator 308 is an oxide layer, other dielectric material may be used as the gate insulator 308. A thickness of the SOI film 303 is within a range approximately from 10 nm to 40 nm, for example. Further, a thickness of the gate insulator 308 is within a range from approximately from 1 nm to 4 nm, for example. It is preferable that the thickness of the SOI film 303 be approximately 20 nm and the thickness of the gate insulator 308 be approximately 2 nm, for example. The gate insulator 308 may be formed before the N-type impurity implanting process.

Next, as shown in FIG. 7A, polysilicon is deposited using, for example, the CVD method to form a non-doped polysilicon layer 307a. A P⁺-type gate electrode 307 shown in FIG. 7C is formed from the non-doped polysilicon layer 307a. A thickness of the polysilicon layer 307a is within a range approximately from 100 nm to 200 nm, and preferably approximately 150 nm, for example.

Next, as shown in FIG. 7A, P-type impurities are implanted into the polysilicon layer 307a. The P-type impurities are boron (B), for example. The P-type impurities are introduced with a dose of approximately 4×10¹⁵ cm⁻² with dose energy of approximately 10 keV. Further, the gate electrode may be doped with boron by reacting a chemical compound including boron such as diborane (B₂H₆) simultaneously with the deposition process of the gate electrode, for example. Through the above-mentioned process, the structure shown in FIG. 7A has been completed.

Next, as shown in FIG. 7B, a non-doped SiO₂ glass (NSG) film 309a is deposited on the polysilicon layer 307a. The NSG film 309a is formed by the CVD method, for example. A thickness of the NSG film 309a is approximately 20 nm, for example. Through the above-mentioned process, the structure shown in FIG. 7B has been completed.

Next, as shown in FIG. 7C, the NSG film 309a and the polysilicon layer 307a are patterned by etching using a desired resist pattern to form the NSG film 309 as a cover layer and the gate electrode 307. A thickness of the gate electrode 307 (i.e., a thickness of the polysilicon layer 307a) is within a range approximately from 100 nm to 200 nm, and preferably approximately 150 nm, for example.

Next, the gate activation annealing is performed to activate P-type impurities introduced in the gate electrode 307 so that the gate electrode 307 is transformed into a P⁺-type polysilicon layer. The gate activation annealing is performed for about 10 sec at a temperature of about 1000 degrees centigrade, for example. The P-type impurity concentration of the gate electrode 307 is approximately 1×10²⁰ cm⁻² or more, for example. The gate electrode 307 is doped with P-type impurities, concentration of which is higher than that of the silicon substrate 301, so that the gate electrode 307 becomes a P⁺-type gate electrode, which is a metal-like conductor. Through the above-mentioned process, the structure shown in FIG. 7C has been completed.

Next, as shown in FIG. 7D, N-type impurities (dopant ions) are implanted into the SOI film 303 using the NSG film 309 and the gate electrode 107 as a self-alignment mask to form a lightly doped drain (LDD) structure. The NSG film 309 is doped with the N-type impurities. Since the NSG film 309 functions as a cover film, the gate electrode 107 disposed below the NSG film 309 are hardly doped with the N-type impurities, which are arsenic (As), for example. The N-type impurities are implanted with dose energy of approximately 5 keV with a dose of approximately 1×10 cm⁻¹. Furthermore, N-type impurities implanted into the SOI film 303 may be phosphorus (P) instead of arsenic.

Next, as shown in FIG. 7D, sidewalls 310 are formed on both side of the gate electrode 307 to form a lightly doped drain (LDD) structure. The sidewalls 310 are made of silicon oxide (SiO₂) or silicon nitride (Si₃N₄), for example.

Next, N-type impurities are implanted into the SOI film 303 using the gate electrode 307 and the sidewalls 310 as a self-alignment mask, thereby forming a source 304, a drain 305, and a body (a channel) 306. The body is disposed below the gate electrode 307 and between the source 304 and the drain 305. Since the N-type impurities are implanted into the NSG film 309, and the sidewalls 310 and the NSG film 309 functions as a cover film, the N-type impurities are hardly implanted into the gate electrode 307. The N-type impurities are, for example, phosphorus (P), and implanted with dose energy of approximately 6 keV with a dose of approximately 5×10 cm⁻². Furthermore, the N-type impurities implanted into the SOI film 303 may be arsenic (As) instead of phosphorus.

Next, in FIG. 7D, source/drain activation annealing is performed to activate N-type impurities introduced into the source 304 and the drain 305, thereby making the source 304 and the drain 305 N-type. The source/drain activation annealing is performed at a temperature of about 975 degrees centigrade for about 10 sec, for example. The N-type impurity concentration in the source 304 and the drain 305 is not less than approximately 1×10²¹ cm⁻². Through the above-mentioned process, the structure shown-in FIG. 7D has been completed.

In addition, a gate length (or a channel length) is within a range approximately from 0.1 μm to 0.25 μm, for example. An advantage of the structure of the P⁺-type gate electrode and the N-type body is remarkable when the SOI MOSFET has a gate length within a range approximately from 0.1 μm to 0.25 μm.

Next, as shown in FIG. 7E, the NSG film 309 is removed. The removing process is performed by wet etching the NSG film 309 using hot phosphoric acid solution as etchant. Through the above-mentioned process, the structure shown in FIG. 7E has been completed.

The NSG film 309 is a non-doped silicon oxide layer immediately after the deposition of the NSG film 309. However wet etching of the NSG 309 (a Phosphosilicate Glass (PSG) film, for example) is performed after the N-type impurities are implanted into the NSG 309 during the source/drain ion implantation. In the wet etching, an etching rate of impurity doped silicon oxide film such as a PSG film is higher than that of a non-doped NSG film. By introducing N-type impurities into the NSG film 309 through the source/drain ion implantation, there is an advantage that an etching rate of the NSG film 309 in the wet etching increases. Further, N-type impurities can be introduced simultaneously with the deposition of the NSG film.

A thickness of the NSG film 309 is determined in accordance with an acceleration voltage at the implantation process of N-type impurities for the LDD ion implantation and the source/drain formation. It is desirable that the thickness of the NSG film 309 be set so as to be able to function as a cover film and to be able to be removed easily. If the NSG film 309 is too thin, it cannot function as a cover film. On the other hand, if the NSG film 309 is too thick, it is difficult to remove it by wet etching because of the existence of the sidewalls 310 made of silicon nitride (Si₃N₄). In the second embodiment, when the NSG film 309 is used as a cover film in the thin film fully-depleted SOI MOSFET, which a thickness of SOI film 303 is approximately 20 nm, a range of the implanted ions in the silicon (Si) of the SOI film 303 is approximately the same as that of silicon oxide (Si0₂) of the cover layer 309. Therefore, it is desirable that a thickness of the NSG film 309 be a junction depth Xi of diffusion layer forming the source and the drain, namely, approximately 20 nm which is the same as a thickness of the SOI film 303.

Since the gate electrode 307 was covered by the NSG film 309 during the LDD ion implantation and the source/drain ion implantation, and N-type impurities are hardly implanted into the gate electrode 307, the P-type impurities concentration of the gate electrode 307 can be kept high. Therefore, the gate electrode 307 is P⁺-type and a metal-like conductor even when the structure shown in FIG. 7E has been completed.

After the formation of the structure shown in FIG. 7E, a silicide layer is formed on the source 304, the drain 305, and the gate electrode 307 for reducing the respective sheet resistances. The silicide layer 304 in the second embodiment is cobalt silicide (CoSi₂) layer, which is formed by reacting silicon (Si) of the silicon surface of the gate electrode, the source, and the drain, and cobalt (Co) after the source/drain ion implantation and the source/drain activation heat treatment. Through the above processes, a silicide gate structure is provided. Since a resistance of a cobalt silicide layer is lower than that of polysilicon of the gate electrode, a gate contact resistance becomes low, and high MOSFET reliability can be obtained. Further, titanium silicide (TiSi₂) layer or a nickel silicide (NiSi) layer may be used in replace of cobalt silicide layer.

After that, an interlayer dielectric is deposited so as to cover the source, the drain, the gate electrode, and the sidewalls, and contact holes are formed in the interlayer dielectric on the source and the drain as in the similar manner to the process shown in FIG. 6F (First Embodiment). Next, contact holes are formed, contact plugs are formed in the contact holes, and metal wiring layers are formed as in the similar manner to the process shown in FIG. 6F (First Embodiment). Through the above processes, the semiconductor device including the SOI MOSFET of the second embodiment has been completed.

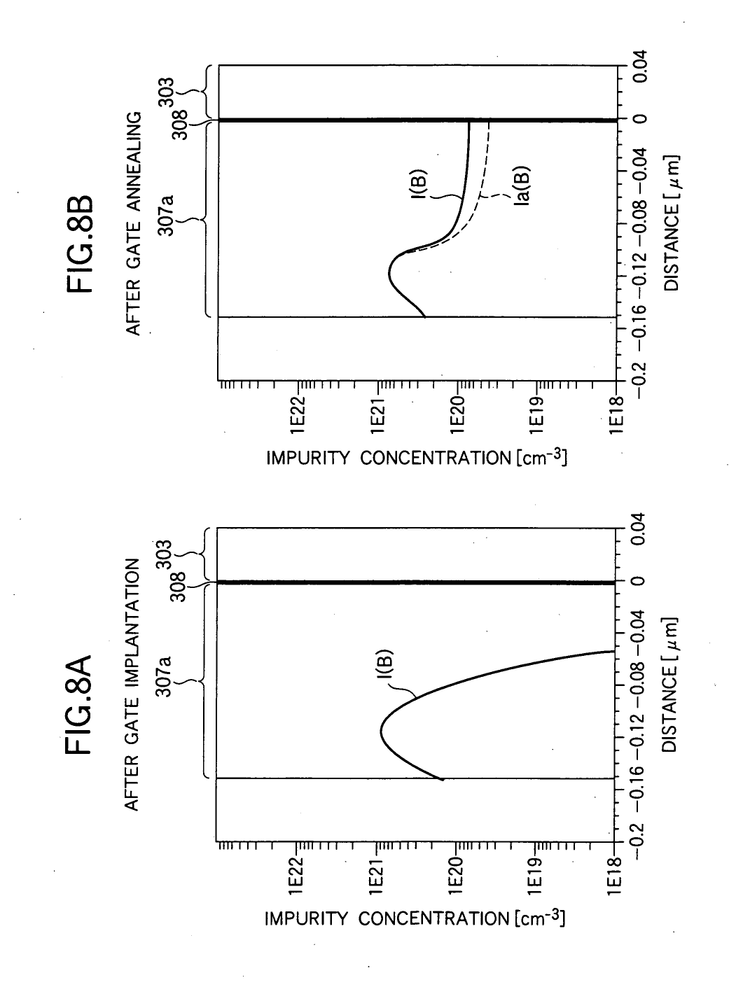

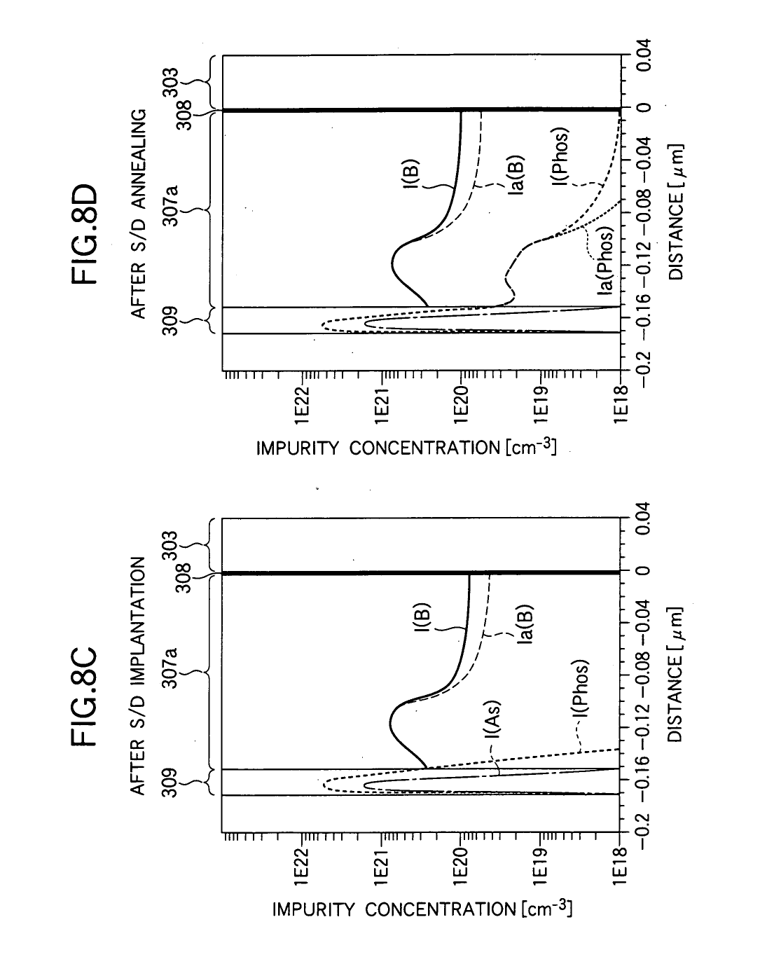

FIGS. 8A to 8D show impurity concentration profiles along a direction of a depth in an SOI MOSFET in accordance with the second embodiment of the present invention. The impurity concentration profiles were obtained by simulations. FIG. 8A shows an impurity concentration profile after the gate ion implantation before the gate activation annealing. FIG. 8B shows an impurity concentration profile after the gate activation annealing after the LDD ion implantation. FIG. 8C shows an impurity concentration profile after the source/drain ion implantation before the source/drain activation annealing. FIG. 8D shows an impurity concentration profile after the source/drain ion implantation.

In FIGS. 8A to 8D, a numeral 303 represents the SOI film, 308 represents the gate insulator, 307a represents the polysilicon layer (or a gate electrode before patterning), 307 represents the gate electrode, and 309 is the NSG film.

In FIGS. 8A to 8D, a curve I(B) indicates an impurity concentration profile of boron (B) implanted with dose energy of 10 keV with a dose of 4×10¹⁵ cm⁻². In FIGS. 8B to 8D, a curve Ia(B) represents an impurity concentration profile of electrically activated boron (B) after the gate activation annealing at a temperature of 1000 degrees centigrade for 10 sec.

In FIGS. 8C and 8D, a curve I(As) indicates an impurity concentration profile of arsenic (As) implanted with dose energy of 5 keV with a dose of 4×10¹⁵ cm² at the LDD ion implantation.

In FIGS. 8C and 8D, a curve I(Phos) indicates an impurity concentration profile of phosphorus (P) implanted with dose energy of 6 keV with a dose of 5×10¹⁵ cm⁻² at the source/drain ion implantation. Further, in FIG. 8D, a curve Ia(Phos) indicates an impurity concentration profile of electrically activated phosphorus (P) after the source/drain activation annealing at a temperature of 1975 degrees centigrade for 10 sec.

As can be understood from FIG. 8C, N-type impurities (arsenic and phosphorus) are implanted into the NSG film 309 mainly, and is hardly implanted into the gate electrode 307 by the NSG film 309 as a cover layer. Further, as can be understood from FIGS. 8B and 8D, even after the source/drain ion implantation and the source/drain activation annealing, the concentration of boron in the gate electrode 307 is kept more than approximately 1×10²⁰ cm⁻³, which is the same level as the concentration before the source/drain ion implantation and the source/drain activation annealing. Therefore, the gate electrode 307 is still a P⁺-type gate electrode, i.e., a metal-like conductor. Furthermore, as can be understood from FIG. 8D, phosphorus is introduced into the gate electrode 307, but this is not a serious problem because the concentration of phosphorus is two orders lower than the concentration of boron in the gate electrode 307.

As described above, the method in accordance with the second embodiment enables to keep the P-type impurity concentration of the gate electrode 307 high, that is, the concentration of 1×10²⁰ cm⁻³. Therefore, the method in accordance with the second embodiment has an advantage that the P⁺-type gate electrode 307 can function as a metal-like conductor.

In the above description, after forming the composite substrate including a silicon substrate 301, an insulating layer 302, and a surface silicon film, the surface silicon film is doped with N-type impurities. However, before bonding the surface silicon film to the silicon substrate 301 so as to form the composite substrate, the surface silicon film (the SOI film 103) may be doped with N-type impurities.

Further, the composite substrate including the silicon substrate 301, the insulating layer 302, and the surface silicon film may be made by the separation by implanting oxygen (SIMOX) method.

In the above description, the sidewalls 310 are made of silicon nitride and the cover film is made of silicon oxide. However, the present invention is not limited to this case. The sidewall 310 may be made of silicon oxide, and the cover film may be made of silicon nitride, for example. The materials of the sidewall 310 and the cover film may be selected so as to optimize the etching selective ratio between the sidewall 310 and the cover film. When the cover film is a silicon nitride film, it is desirable that a thickness of the cover film be approximately 14 nm to 15 nm. This is because a range distance of an implanted ion in the silicon nitride film is about 70% of a range distance in a silicon layer.

Third Embodiment

In the second embodiment, an NSG film 309 as a cover film is formed on the P⁺-type gate electrode 307 in order to avoid introducing N-type impurities into the P⁺-type gate electrode 307, and removed the NSG film 309 after the source/drain activation annealing in order to form a silicide layer for reducing the sheet resistance (which is not illustrated in FIGS. 7A to 7E, but illustrated in FIG. 1 as a member 117) on the gate electrode 307.

In the third embodiment, instead of the NSG film 309 illustrated in FIG. 7D, a silicide layer is formed as a cover film on the P⁺-type gate electrode 307 in order to avoid introducing N-type impurities into the P⁺-type gate electrode 307. Since the silicide layer has a function of reducing the sheet resistance, a removal process of the silicide layer as the cover layer can be omitted.

A tungsten silicide (WSiₓ) layer can be used as the silicide layer, which functions as both a cover film and a layer for reducing the sheet resistance. The tungsten silicide layer can be formed using the sputtering method. A polycide gate structure, which is composed of the, tungsten silicide layer and the polysilicon layer, can be obtained. When the polycide gate structure is applied to the thin film SOI MOSFET having the SOI film 303 of approximately 20 nm thickness, it is desirable that a thickness of the tungsten silicide layer (which corresponds to the layer 309 in FIG. 7D) be approximately 80 nm.

Furthermore, a sheet resistance reduction effect of the tungsten silicide layer is less than that of a cobalt silicide layer. However, the tungsten silicide layer has an advantage that it is hardly introduced into the polysilicon gate electrode during the annealing process.

As described above, the method in accordance with the third embodiment has an advantage that the P⁺-type gate electrode 307 functions as a metal-like conductor as in the similar manner to the second embodiment and the removal process of the cover film can be omitted.

The invention being thus described, it will be obvious that the same may be varied in many ways. Such variations are not to be regarded as a departure from the spirit and scope of the invention, and all such modifications as would be obvious to one skilled in the art are intended to be included within the scope of following claims.

What is claimed is:

1. A semiconductor device comprising:
a semiconductor substrate;
an insulating layer disposed on said semiconductor substrate;
an SOI film disposed on said insulating layer;
a gate insulator disposed on said SOI film; and
a gate electrode disposed on said gate insulator;
wherein a source, a drain, and a channel are formed in said SOI film so that said gate insulator is located at least between said channel and said gate electrode, thereby forming a MOSFET including said source, said drain, said channel, said gate electrode, and said gate insulator; and
wherein said gate electrode is made of P-type polysilicon and said channel is N-type.

2. The semiconductor device according to claim 1, wherein an N-type impurity concentration in said channel is within a range approximately from 1×10¹⁷ cm⁻³ to 1×10¹⁸ cm⁻³.

3. The semiconductor device according to claim 2, wherein said N-type impurity concentration in said channel is approximately 3×10¹⁷ cm⁻³.

4. The semiconductor device according to claim 1, wherein a thickness of said gate insulator is within a range approximately from 1 nm to 4 nm, and a thickness of said SOI film is within a range approximately from 10 nm to 40 nm.

5. The semiconductor device according to claim 4, wherein said thickness of said gate insulator is approximately 2 nm, and said thickness of said SOI film is approximately 20 nm.

6. The semiconductor device according to claim 1, wherein said source and said drain are doped with N-type impurities so that an N-type impurity concentration in said source and said drain is not less than approximately 1×10²¹ cm⁻³.

7. The semiconductor device according to claim 1, wherein a channel length of said channel is within a range approximately from 0.1 μm to 0.25 μm.

8. The semiconductor device according to claim 7, wherein said channel length of said channel is approximately 0.15 μm.

9. A metal-oxide-semiconductor field-effect transistor comprising:
a semiconductor substrate having a substrate, an insulating layer which is disposed on the substrate and a silicon layer which is disposed on the insulating layer;
a gate insulator disposed on the silicon layer of the semiconductor substrate;
a gate electrode, which is made of P-type polysilicon, disposed on the semiconductor substrate so that the gate insulator is disposed between the gate electrode and the semiconductor substrate;
a channel region formed in the silicon layer, which is located under the gate electrode; and
a source and a drain formed in the silicon layer and being adjacent to the channel region;
wherein conductivity types of the channel region, the source and the drain are N-type.

10. The metal-oxide-semiconductor field-effect transistor according to claim 9, wherein an N-type impurity concentration in the channel region is within a range approximately from 1×10¹⁷ cm⁻³ to 1×10¹⁸ cm⁻³.

11. The metal-oxide-semiconductor field-effect transistor according to claim 10, wherein the N-type impurity concentration in the channel region is approximately 3×10¹⁷ cm⁻³.

12. The metal-oxide-semiconductor field-effect transistor according to claim 9, wherein a thickness of the gate insulator is within a range approximately from 1 nm to 4 nm, and a thickness of the silicon layer is within a range approximately from 10 nm to 40 nm.

13. The metal-oxide-semiconductor field-effect transistor according to claim 12, wherein the thickness of the gate insulator is approximately 2 nm, and the thickness of the silicon layer is approximately 20 nm.

14. The metal-oxide-semiconductor field-effect transistor according to claim 9, wherein the source and the drain are doped with N-type impurities so that an N-type impurity concentration in the source and the drain is not less than approximately 1×10²¹ cm⁻³.

15. The metal-oxide-semiconductor field-effect transistor according to claim 9, wherein a channel length of the channel region is within a range approximately from 0.1 μm to 0.25 μm.

16. The metal-oxide-semiconductor field-effect transistor according to claim 15, wherein the channel length of the channel region is approximately 0.15 μm.
